(19) United States
(12) Patent Application Publication
(10) Pub. No.: US 2015/0301452 A1
(43) Pub. Date: Oct. 22, 2015

(54) PHOTORESIST COMPOSITION AND METHOD OF FABRICATING DISPLAY SUBSTRATE USING THE SAME

(71) Applicant: Samsung Display Co., Ltd., Yongin-City (KR)

(72) Inventors: Jeong-Min Park, Yongin-City (KR); Jun Chun, Yongin-City (KR); Ji-Hyun Kim, Yongin-City (KR); Sung-Kyun Park, Yongin-City (KR); Jung-Soo Lee, Yongin-City (KR); Ki-Hyun Cho, Yongin-City (KR); Jin-Ho Ju, Yongin-City (KR); Chang-Ik Lee, Anseong-si (KR); Se-Tae Oh, Anseong-si (KR); Deok-Man Kang, Anseong-si (KR)

(21) Appl. No.: 14/503,062

(22) Filed: Sep. 30, 2014

(30) Foreign Application Priority Data
Apr. 17, 2014 (KR) 10-2014-0046193

(51) Int. Cl. G03F 7/038; C23F 1/02; C23F 1/16; G03F 7/16; G03F 7/40

(52) U.S. Cl. CPC G03F 7/0382; G03F 7/16; G03F 7/40; C23F 1/16; C23F 1/02

(57) ABSTRACT

A chemically amplified photoresist composition is provided which includes: a solute including a novolac resin with an acid decomposable protecting group, a photoacid generator, and an organic solvent.

### INCORPORATION BY REFERENCE TO ANY PRIORITY APPLICATIONS

Any and all priority claims identified in the Application Data Sheet, or any correction thereto, are hereby incorporated by reference under 37 CFR 1.57. For example, this application claims the benefit of Korean Patent Application No. 10-2014-0046193, filed, in the Korean Intellectual Property Office on Apr. 17, 2014, the disclosure of which is incorporated herein in its entirety by reference.

### BACKGROUND

1. Field

The disclosure relates to photoresist compositions, and methods of fabricating display substrates using the same.

2. Description of the Related Technology

Novolac-diazonaphthoquinone (DNQ) photoresists are used to fabricate back planes for flat panel displays. Novolac resin is normally soluble in an alkali developing solution, but is not soluble when mixed with DNQ. When DNQ in the photoresist is changed into indene carboxylic acid by exposure to light, the photoresist may become soluble in the developing solution. Since the novolac-DNQ photoresist has a degree of solubility in a developing solution, it may cause a limit to the resolution and contrast of displays. This drawback is addressed by the use of chemically amplified photoresist.

Chemically amplified photoresist uses a photoacid generator (PAG) that is decomposed by light absorption to generate a strong acid. While the strong acid generated in an exposed region of a photoresist layer is diffused into the photoresist layer during post baking, it may serve as a catalyst to facilitate removal of a protecting group on the photoresist resin into a hydroxyl group, which consequently makes the photoresist resin soluble in the developing solution.

Chemically amplified photoresist includes polyhydroxystyrene (PHS) or acryl resin. These resins are not soluble in the developing solution, and become soluble by a photoacid generator only in a region exposed to light, and thus provide high resolution and high contrast compared to the Novolac-DNQ photoresist. However, the chemically amplified photoresist may react with an acid, and thus may be taken away from a substrate and cause a pattern failure such as an undercut, due to an etch solution including acid.

### SUMMARY

One or more embodiments of the present disclosure include a photoresist having improved resolution and improved contrast and that may not separate from a substrate or may not lead to a pattern failure caused by an etch solution.

Additional aspects will be set forth in part in the description which follows and, in part, will be apparent from the description, or may be learned by practice of the presented embodiments.

According to one or more embodiments of the present disclosure, a photoresist composition includes: a solute including a novolac resin with an acid decomposable protecting group, a photoacid generator; and an organic solvent.

The amount of the solute may be in a range of about 10 wt % to about 40 wt % based on a total weight of the chemically amplified photoresist composition, and the amount of the organic solvent may be the remaining weight of the chemically amplified photoresist composition.

The solute may further include a polyhydroxystyrene resin with an acid decomposable protecting group or an acrylic resin acid with an acid decomposable protecting group, and an amount of the novolac resin in the solute may be in a range of about 40 wt % or greater to less than 100 wt % based on the weight of the solute.

The acid decomposable protecting group of the novolac resin may substitute for part of a hydroxyl group of the novolac resin, and the acid decomposable protecting group may include a tert-butyl group, a tert-butoxycarbonyl group, a tert-butoxycarbonylmethyl group, a tetrahydro-2-pyranyl group, a tetrahydro-2-furyl group, a 1-ethoxyethyl group, a 1-(2-methylpropoxyl)ethyl group, a 1-(2-methoxyethoxy)ethyl group, a 1-(2-acetoxyethoxyl)ethyl group, a 1-[2-(1-adamantyloxy)ethoxy]ethyl group, a 1-[2-(1-adamantanecarbonyloxyl)ethoxy]ethyl group, a 3-oxocyclohexyl group, a 4-methyltetrahydro-2-pyrone-4-yl group, a 2-methyl-2-adamantyl group, or a 2-ethyl-2-adamantyl group.

A mole ratio of the acid decomposable protecting group to a hydroxyl group in the novolac resin may be in a range of about 10:90 to about 40:60.

A mole ratio of the acid decomposable protecting group in the polyhydroxystyrene resin or the acrylic resin to a hydroxyl group in the polyhydroxystyrene resin or the acrylic resin may be in a range of about 20:80 to about 50:50.

The photoacid generator may generate an acid in a wavelength range of light of about 365 nm to about 435 nm.

According to one or more embodiments of the present disclosure, a method of fabricating a display substrate includes: forming a conductive layer including a conductive material on a substrate; forming an etch mask pattern from a photoresist composition on the conductive layer; etching the conductive layer by using the etch mask pattern as an etch mask to form a conductive layer pattern, wherein the photoresist composition may include: a solute including a novolac resin with an acid decomposable protecting group, a photoacid generator; and an organic solvent.

The etching of the conductive layer may be performed by wet etching using an etch solution.

### BRIEF DESCRIPTION OF THE DRAWINGS

These and/or other aspects will become apparent and more readily appreciated from the following description of the embodiments, taken in conjunction with the accompanying drawings in which:

FIGS. 1A to 1I are schematic cross-sectional views for explaining a method of fabricating a display substrate according to an embodiment of the present disclosure; and

FIG. 2 is a schematic view illustrating an undercut.

### DETAILED DESCRIPTION

Reference will now be made in detail to embodiments, examples of which are illustrated in the accompanying drawings, wherein like reference numerals refer to like elements throughout. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. As used herein, the term “and/or” includes any and all combinations of one or more of the associated listed items. Expressions such as “at least one of,” when preceding a list of elements, modify the entire list of elements and do not modify the individual elements of the list.

Hereinafter, chemically amplified photoresist compositions according to embodiments of the present disclosure will be described in greater detail.

According to an embodiment, a chemically amplified photoresist composition includes: a solute including a novolac resin with an acid decomposable protecting group, and a photoacid generator; and an organic solvent.

The novolac resin may be obtained by addition condensation reaction of a phenol-based compound with an aldehyde-based compound or a ketone-based compound.

For example, the novolac resin may be obtained by reacting a phenol compound mixture in which meta-cresol (m-cresol) and para-cresol (p-cresol) are mixed in a weight ratio of about 40:60 to about 100:0, with formaldehyde.

Non-limiting examples of the phenol-based compound that may be used to prepare the novolac resin are phenol, ortho-cresol (o-cresol), meta-cresol (m-cresol), para-cresol (p-cresol), 2,5-xylenol, 3,5-xylenol, 3,4-xylenol, 2,3,5-trimethylphenol, 4-t-butylphenol, 2-t-butylphenol, 3-t-butylphenol, 3-ethylphenol, 2-ethylphenol, 4-ethylphenol, 3-methyl-6-t-butylphenol, 4-methyl-2-t-butylphenol, 2-naphthol, 1,3-dihydroxynaphthalene, 1,7-dihydroxynaphthalene, or 1,5-dihydroxynaphthalene, which may be used alone or in combination.

Non-limiting examples of the aldehyde-based compound that may be used to prepare the novolac resin are formaldehyde, para-formaldehyde, acetaldehyde, propylaldehyde, benzaldehyde, phenylaldehyde, α-phenylpropylaldehyde, β-phenylpropylaldehyde, o-hydroxybenzaldehyde, m-hydroxybenzaldehyde, p-hydroxybenzaldehyde, glutaraldehyde, glyoxal, o-methylbenzaldehyde, or methylbenzaldehyde, which may be used alone or in combination.

Non-limiting examples of the ketone-based compound that may be used to prepare the novolac resin are acetone, methylethylketone, diethylketone, or diphenylketone, which may be used alone or in combination.

The acid decomposable protecting group of the novolac resin, which is a functional group that makes the novolac resin insoluble in an alkali developing solution, may make the novolac resin soluble in the alkali developing solution when decomposed into a hydroxyl group by acid.

Non-limiting examples of the acid decomposable protecting group are a tert-butyl group, a tert-butoxycarbonyl group, a tert-butoxycarbonylmethyl group, a tetrahydro-2-pyranyl group, a tetrahydro-2-furyl group, a 1-ethoxyethyl group, a 1-(2-methylpropoxyl)ethyl group, a 1-(2-methoxyethoxyl)ethyl group, a 1-(2-acetoxyethoxyl)ethyl group, a 1-[2-(1-adamantyloxy)ethoxy]ethyl group, a 1-[2-(1-adamantanecarbonyloxyl)ethoxy]ethyl group, a 3-oxocyclohexyl group, a 4-methyltetrahydro-2-pyrone-4-yl group, 2-methyl-2-adamantyl group, and a 2-ethyl-2-adamantyl group. The acid decomposable protecting group substitutes for a hydrogen atom in a hydroxyl group of the novolac resin. The acid decomposable protecting group may be introduced into the hydroxyl group of the novolac resin by a common protecting group introduction reaction.

A mole ratio of the acid decomposable protecting group to hydroxyl group in the novolac resin may be in a range of about 10:90 to about 40:60.

An amount of the novolac resin in the solute of the chemically amplified photoresist composition may be in a range of about 40 wt % or greater to less than 100 wt %, and in some embodiments, about 40 wt % or greater to about 97 wt % or less, and in some other embodiments, about 40 wt % or greater to about 70 wt % or less, and in still other embodiments, about 40 wt % or greater to about 50 wt % or less, based on weight of the solute.

The chemically amplified photoresist composition may further include, in addition to the novolac resin, a polyhydroxystyrene resin with an acid decomposable protecting group or an acrylic resin acid with an acid decomposable protecting group.

Non-limiting examples of the acid decomposable protecting group of the polyhydroxystyrene resin or the acrylic resin include, like those of the acid decomposable protecting group of the novolac resin, a tert-butyl group, a tert-butoxycarbonyl group, a tert-butoxycarbonylmethyl group, a tetrahydro-2-pyranyl group, a tetrahydro-2-furyl group, a 1-ethoxyethyl group, a 1-(2-methylpropoxyl)ethyl group, a 1-(2-methoxyethoxyl)ethyl group, a 1-(2-acetoxyethoxyl)ethyl group, a 1-[2-(1-adamantyloxy)ethoxy]ethyl group, a 1-[2-(1-adamantanecarbonyloxyl)ethoxy]ethyl group, a 3-oxocyclohexyl group, a 4-methyltetrahydro-2-pyrone-4-yl group, 2-methyl-2-adamantyl group, and a 2-ethyl-2-adamantyl group. The acid decomposable protecting group substitutes for a hydrogen atom in a hydroxyl group of the polyhydroxystyrene resin or a hydrogen atom in a carboxyl group of the acrylic resin.

A mole ratio of the acid decomposable protecting group to hydroxyl group in the polyhydroxystyrene resin or the acrylic resin may be in a range of about 20:80 to about 50:50.

The amount of the novolac resin may be in a range of about 5 wt % to about 50 wt %, and in some embodiments, about 8 wt % to about 30 wt %, based on the total weight of the photoresist composition.

When the photoresist composition further includes, in addition to the novolac resin with an acid decomposable protecting group, a polyhydroxystyrene resin with an acid decomposable protecting group, or an acrylic resin with an acid decomposable protecting group, an amount of the resin mixture may be in a range of about 5 wt % to about 50 wt %, and in some embodiments, about 8 wt % to about 30 wt %, based on the weight of the solute.

The novolac resin with an acid decomposable protecting group may have a weight average molecular weight of about 1,000 to about 30,000. When the weight average molecular weight of the novolac resin is less than about 1,000, the novolac resin may be easily dissolved and lost in an alkali developing solution. When the weight average molecular weight of the novolac resin exceeds about 30,000, a solubility difference between exposed and unexposed regions of the photoresist in an alkali developing solution may be too small to attain a sharp photoresist pattern.

The polyhydroxystyrene resin with an acid decomposable protecting group may have a weight average molecular weight of about 3,000 to about 30,000. The acrylic resin with an acid decomposable protecting group may have a weight average molecular weight of about 3,000 to about 100,000. When the weight average molecular weights of the polyhydroxystyrene resin and the acrylic resin are within these ranges, it is possible to obtain a sharp photoresist patter.

The photoacid generator (PAG) may generate an acid via exposure to light. While an acid generated by the photoacid generator in an exposed region of a photoresist layer is diffused into the photoresist layer during post baking, it may serve as a catalyst to facilitate decomposition of the acid decomposable protecting group of the photoresist resin into a hydroxyl group. This hydroxyl group may make the chemically amplified photoresist resin soluble in a developing solution.

Non-limiting examples of the photoacid generator are a substituted or unsubstituted benzophenone compound, a substituted or unsubstituted triazine compound, and a substituted or unsubstituted sulfonium compound. For example, the photoacid generator may include 4-methoxyphenylphenyliodonium trifluoromethanesulfonate, bis(4-tert-butylphenyl)iodonium trifluoromethanesulfonate, triphenylsulfonium trifluoromethanesulfonate, tri(4-methylphenyl)sulfonium trifluoromethanesulfonate, 2,4,6-trimethylphenyldiphenylsulfonium trifluoromethanesulfonate, 1-(2-naphtholylmethyl)thoranium trifluoromethanesulfonate, 4-hydroxy-1-naphthyldimethylsulfonium trifluoromethanesulfonate, cyclohexylmethyl(2-oxocyclohexyl)sulfonium trifluoromethanesulfonate, 2-methyl-4,6-bis(trichloromethyl)-1,3,5-triazine, 2,4,6-tris(trichloromethyl)-1,3,5-triazine, 2-phenyl-4,6-bis(trichloromethyl)-1,3,5-triazine, 2-(4-methoxyphenyl)-4,6-bis(trichloromethyl)-1,3,5-triazine, 2-(4-methoxystyryl)-4,6-bis(trichloromethyl)-1,3,5-triazine, 2-(2,4-dimethoxystyryl)-4,6-bis(trichloromethyl)-1,3,5-triazine, 2-(2-methoxystyryl)-4,6-bis(trichloromethyl)-1,3,5-triazine, 1-benzoyl-1-phenylmethyl p-toluenesulfonate, 2-benzoyl-2-hydroxy-2-phenylethyl p-toluenesulfonate, 1,2,3-benzene-triyl-tris(methanesulfonate), 2-dinitrobenzyl p-toluenesulfonate, or 4-nitrobenzyl p-toluenesulfonate.

The amount of the photoacid generator may be in a range of about 0.01 wt % to about 10 wt %, and in some embodiments, about 0.1 wt % to about 5 wt %, based on the total weight of the photoresist composition.

The chemically amplified photoresist composition may further include an additive. Non-limiting examples of the additive may include a surfactant, an adhesion enhancer, a neutralizing agent, or a UV light absorber.

The surfactant may improve coating properties or developing properties of the photoresist composition. Non-limiting examples of the surfactant are polyoxyethylene octylphenyl ether, polyoxyethylene nonylphenyl ether, F171, F172, F173 (Product names of Dainippon Ink Co., Tokyo, Japan), FC430, FC431 (Product names of Sumitomo 3-M Co., Tokyo, Japan), and KP341 (Product name of Shin-Etsu Chemical Co. Ltd., Tokyo, Japan), which may be used alone or in combination.

The adhesion enhancer may improve the adhesion between a substrate and a photoresist pattern. A non-limiting example of the adhesion enhancer is a silane coupling agent having a reactive substituent group such as a carboxyl group, a methacryl group, an isocyanate group, or an epoxy group. Non-limiting examples of the silane coupling agent having such a reactive substituent group are γ-methacryloxypropyltrimethoxysilane, vinyltriacetoxysilane, vinyltrimethoxysilane, γ-isocyanatopropyltriethoxysilane, γ-glycidoxypropyltrimethoxysilane, and β-(3,4-epoxycyclohexyl)ethyltrimethoxysilane, which may be used alone or in combination.

The neutralizing agent may prevent diffusion of an acid that is generated by the photoacid generator via exposure to light. Non-limiting examples of the neutralizing agent are amines, such as ethylamine, propylamine, butylamine, diisopropylaniline, diisopropylamine, and (2-(2,2,2-trimethoxyethoxyl)ethan-1-amine).

In the chemically amplified photoresist composition, the amount of the additive may be determined based on a total amount of the novolac resin, the photoacid generator, and the organic solvent. To prevent influence of the additive on the reaction of the novolac resin and the photoacid generator, the amount of the additive may be in a range of about 0 wt % to about 1 wt % based on the total weight of the photoresist composition.

Non-limiting examples of the organic solvent are ethers, glycol ethers, ethylene glycol alkyl ether acetates, diethylene glycol, propylene glycol monoalkyl ethers, propylene glycol alkyl ether acetates, aromatic hydrocarbons, ketones, or esters. For example, the organic solvent may include propylene glycol monoethyl acetate, propylene glycol monoethyl ether, ethyl lactate, benzyl alcohol, methyl acetate, ethyl acetate, n-butyl acetate, isobutyl acetate, propyl acetate, or, 3-methylmethoxy propionate (methyl 3-methoxy propionate).

The amount of the organic solvent may be in a range of about 60 wt % to about 90 wt % based on the total weight of the photoresist composition.

Hereinafter, methods of fabricating display substrates using any of the chemically amplified photoresist compositions as described above according to embodiments of the present disclosure will be described in greater detail.

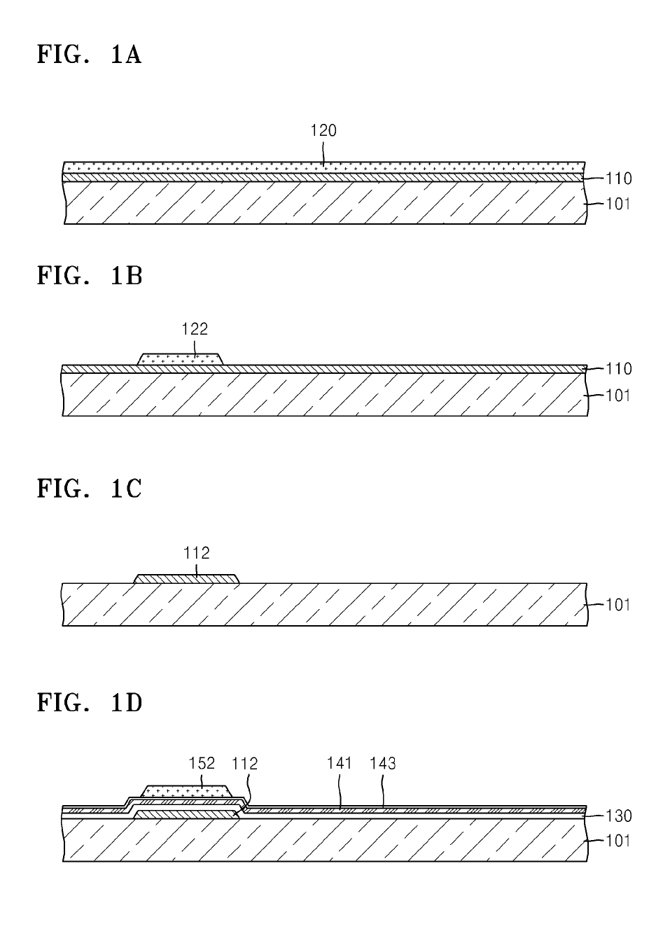

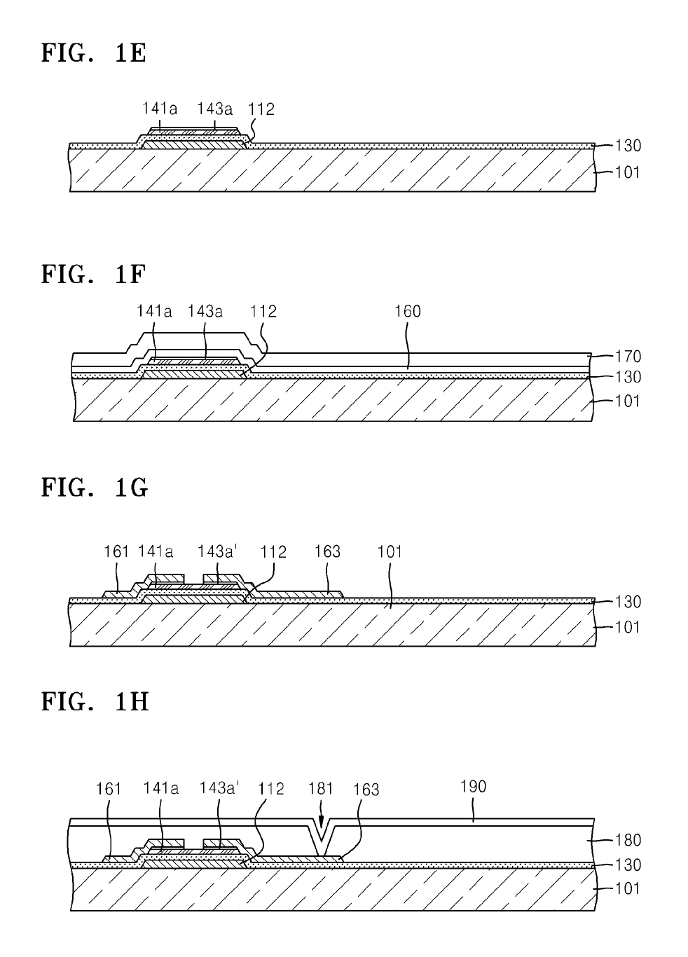

FIGS. 1A to I are schematic cross-sectional views for explaining a method of fabricating a display substrate according to an embodiment of the present disclosure. In the embodiment of FIGS. 1A to 1I, the display substrate may include a thin film transistor (TFT).

Referring to FIG. 1A, a gate metal layer 110 and a first photoresist layer 120 may be sequentially formed on a substrate 101.

The substrate 101 may be a glass substrate formed of, for example, soda lime glass or borosilicate glass, or a plastic substrate formed of, for example, polyether sulfone or polycarbonate. For example, the substrate 101 may be a flexible substrate formed of, for example, polyimide.

The gate metal layer 110 may be formed by sputtering metal onto the substrate 101. For example, the gate metal layer 110 may include an aluminum-based metal such as aluminum (Al) or an Al alloy, a silver-based metal such as silver (Ag) or an Ag alloy, a copper-based metal such as copper (Cu) or a copper alloy, a molybdenum-based metal such as molybdenum (Mo) or an Mo alloy, chromium (Cr), titanium (Ti), or tantalum (Ta). The gate metal layer 110 may have a multilayer structure including two conductive layers (not shown) having different physical characteristics. One of the conductive layers may include a metal having low resistivity to suppress a signal delay or a voltage drop, for example, an Al-based metal or an Ag-based metal. The other conductive layer may include a metal having good contact characteristics with other materials, for example, a Mo-based metal, Cr, Ti, or Ta. For example, the multilayer structure of the metal gate layer 110 may be a structure including a Cr lower layer and an Al upper layer, a structure including an Al lower layer and a Mo upper layer, or a structure including a Mo lower layer, an Al intermediate layer, and a Mo upper layer, but is not limited thereto.

The first photoresist layer 120 may be formed by applying a chemically amplified photoresist composition onto the gate metal layer 110. The chemically amplified photoresist composition may be applied onto the gate metal layer 110 by spin coating or slit coating.

The chemically amplified photoresist composition may include: a solute including a novolac resin with an acid decomposable protecting group and a photoacid generator, and an organic solvent. The chemically amplified photoresist composition may be substantially the same as a chemically amplified photoresist composition according to any of the above-described embodiments.

While a first mask (not shown) is disposed on the first photoresist layer 120 of the substrate 101, the first photoresist layer 120 is exposed to light radiated from above the first mask. The light may be ultraviolet (UV) rays having a wavelength of about 365 nm to about 435 nm. The light may include UV rays having multiple wavelengths within this range.

Referring to FIG. 1B, the first photoresist layer 120 (shown in FIG. 1A) may be subjected to post baking, followed by a development process using a developing solution to form a first photoresist pattern 122. An acid may be generated in an exposed region of the first photoresist layer 120 by the photoacid generator, and may be diffused into the first photoresist layer 120 via the post baking to serve as a catalyst to facilitate decomposition of the acid decomposable protecting group in the photoresist so that the exposed region of the first photoresist layer 112 (shown in FIG. 1C), which is originally insoluble in a developing solution before the exposure process, may become soluble in the developing solution, and be removed from the first photoresist layer 120. The post baking process may be omitted, if possible. For example, when the acid decomposable protecting group is also photo-decomposable, and is decomposable by light energy only, the post baking process may be omitted.

Referring to FIG. 1C, after the gate metal layer 110 (shown in FIG. 1B) is etched using the first photoresist pattern 122 (shown in FIG. 1B) as an etch mask to form a gate electrode 112, the first photoresist pattern 122 may be removed. The gate metal layer 110 may be etched using an etch solution, for example, an aqueous solution such as nitric acid, sulfuric acid, hydrochloric acid, phosphoric acid, or a mixture thereof. The first photoresist pattern 122 may be removed using, for example, a strip solution.

Although when the gate metal layer 110 is etched using an etch solution, occurrence of an undercut in a region of the gate metal layer 110 that contacts the first photoresist pattern 122 may be suppressed due to the strong adhesion between the first photoresist pattern 122 and the gate metal layer 110 (shown in FIG. 1B). Although not limited to specific mechanism, the mechanism to reduce the undercut of the gate metal layer 110 is attributed to the novolac resin which has a dense structure in which the acid decomposable protecting group of the novolac resin is shielded by a 3-dimensional backbone structure to reduce damage from acid in the etching solution.

Referring to FIG. 1D, a gate insulating layer 130, a semiconductor layer 141, an ohmic contact layer 143, and a second photoresist layer (not shown) may be sequentially formed on the substrate 101 with the gate electrode 112 thereon.

The gate insulating layer 130 may be formed of, for example, silicon oxide or silicon nitride by, for example, thermal oxidation or chemical vapor deposition (CVD).

The semiconductor layer 141 may be formed on the gate insulating layer 130. For example, the semiconductor layer 141 may be formed of amorphous silicon (a-Si) or polycrystalline silicon by, for example, CVD.

The ohmic contact layer 143 may be formed on the semiconductor layer 141. The ohmic contact layer 143 may be include amorphous silicon heavily doped with n-type impurities (n+a-Si) or polycrystalline silicon heavily doped with n-type impurities.

Although not shown, the second photoresist layer may be formed using a chemically amplified photoresist composition according to any of the above-described embodiments of the present disclosure. The second photoresist layer may be patterned using a second mask (not shown) into a second photoresist pattern 152 via exposure to light, post baking, and a development process. The photoresist composition may be the same as described above, and a method of forming the second photoresist pattern 152 may be the same as the above-described method of forming the first photoresist pattern 122, and thus detailed descriptions thereof will be omitted here.

Referring to FIG. 1E, the semiconductor layer 141 and the ohmic contact layer 143 (shown in FIG. 1D) may be etched using the second photoresist pattern 152 (shown in FIG. 1D) as an etch mask to form an active layer pattern 141a and an ohmic contact layer pattern 143a, respectively. The etching to form the active layer pattern 141a and the ohmic contact layer pattern 143a may be an individual or integrated wet or dry etching. In wet etching, for example, an etch solution as a mixture of, for example, hydrofluoric acid (HF), sulfuric acid, hydrochloric acid, or a combination thereof with deionized water may be used. In dry etching, a fluorine-based etch gas, for example, CHF₃ or CF₄ may be used.

Referring to FIG. 1F, a conductive layer 160 (shown in FIG. 1F) for data interconnect and a third photoresist layer 170 may be sequentially formed on the substrate 101 with the active layer pattern 141a and the ohmic contact layer pattern 143a thereon.

The conductive layer 160 for data interconnect may be formed as a single layer or a multilayer including, for example, nickel (Ni), cobalt (Co), titanium (Ti), silver (Ag), copper (Cu), molybdenum (Mo), aluminum (Al), beryllium (Be), niobium (Nb), gold (Au), iron (Fe), selenium (Se), or tantalum (Ta) by, for example, CVD or sputtering. The multilayer may be a double layer of, for example, Ta/Al, Ta/Al, Ni/Al, Co/Al, Mo (Mo alloy)/Cu, or a triple layer of, for example, Ti/Al/Ti, Ta/Al/Ta, Ti/Al/TiN, Ta/Al/TaN, Ni/Al/Ni, or Co/Al/Co.

The third photoresist layer 170 may be formed using a chemically amplified photoresist composition according to any of the above-described embodiments of the present disclosure. The third photoresist layer 170 may be patterned using a third mask (not shown) into a third photoresist pattern (not shown) via exposure to light, post baking, and a development process. The photoresist composition may be the same as described above, and a method of forming the third photoresist pattern may be the same as the above-described method of forming the first photoresist pattern 122, and thus detailed descriptions thereof will be omitted here.

Referring to FIG. 1G, the conductive layer 160 for data interconnect (shown in FIG. 1F) may be etched using the third photoresist pattern as an etch mask to form a source electrode 161 and a drain electrode 163. The etching to form the source electrode 161 and the drain electrode 163 may be wet etching or dry etching. In wet etching, for example, a mixed solution of phosphoric acid, nitric acid, and acetic acid, or a mixed solution of hydrofluoric acid (HF) and deionized water may be used as an etch solution. When etching the conductive layer 160 for data interconnect using the third photoresist pattern, the ohmic contact layer pattern 143a may be etched into separate ohmic contact layer patterns 143a′ so as to overlap with the source electrode 161 and the drain electrode 163 respectively.

Referring to FIG. 1H, an interlayer insulating layer 180 may be formed on the substrate 101 with the source electrode 161 and the drain electrode 163 thereon. While a fourth photoresist pattern (not shown) is formed on the interlayer insulating layer 180, the interlayer insulating layer 180 may be etched to form a contact hole 181 to expose the drain electrode 163. Subsequently, a conductive layer 190 for a pixel electrode may be formed of a transparent conductive oxide such as ITO or IZO, or a reflective conductive material. The conductive layer 190 for a pixel electrode may be formed on the interlayer insulating layer 180 with the contact hole 181 by, for example, sputtering.

The fourth photoresist layer may be formed using a chemically amplified photoresist composition according to any of the above-described embodiments of the present disclosure. Forming a fourth photoresist pattern (not shown) from the fourth photoresist layer and forming a pixel electrode 191 by etching the conductive layer 190 for a pixel electrode may be inferred from the method of forming the first photoresist pattern 122 and the method of forming the gate electrode 122 as described above, respectively, and thus detailed descriptions thereof will be omitted here.

Referring to FIG. 1I, while a fifth photoresist pattern (not shown) is formed on the conductive layer 190 for a pixel electrode, the conductive layer 190 (shown in FIG. 1H) may be etched to form the pixel electrode 191. The pixel electrode 191 may contact the drain electrode 163 via the contact hole 181, and may be electrically connected with a thin film transistor (TFT).

The chemically amplified photoresist compositions according to the above-described embodiments of the present disclosure may be used to manufacture display substrate having various structures, not only such structures as described above. The chemically amplified photoresist compositions according to the above-described embodiments of the present disclosure may also be used to manufacture various semiconductor devices and electronic devices.

One or more embodiments of the present disclosure will now be described in detail with reference to the following examples. However, these examples are only for illustrative purposes and are not intended to limit the scope of the one or more embodiments of the present disclosure.

### Example 1

A novolac resin with an acid decomposable (also photo-decomposable) protecting group was prepared as a base resin by substituting 20% (by mole) of the hydroxyl groups of a novolac resin with 1-ethoxy-ethoxy groups

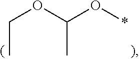 [SMILES: *OC(C)OCC]

wherein the novolac resin used to prepare the base resin had a weight ratio of 60:40 between meta-cresol (m-cresol) and para-cresol (p-cresol), and a weight average molecular weight of about 10,000.

Solid components (including any solutes except for solvent), i.e., 96.9 wt % of the novolac resin as base resin having an acid decomposable protecting group, 3 wt % of Compound 1 (2-styryl-4,6-bis(trichloromethyl)-1,3,5-triazine) as a photoacid generator (PAG), and 0.1 wt % of a silicon-based surfactant were mixed with propylene glycol monoethyl acetate used as a solvent to prepare a photoresist composition. A weight ratio of the solute to the solvent in the photoresist composition was about 25:75.

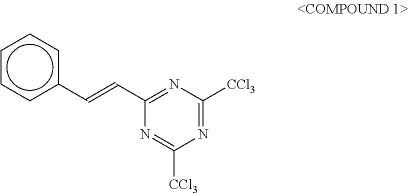

### Example 2

A novolac resin with an acid decomposable protecting group was prepared as a base resin by substituting 20% (by mole) of a hydroxyl group of a novolac resin with 1-ethoxy-ethoxy groups, wherein the novolac resin used to prepare the base resin had a weight ratio of 60:40 between meta-cresol (m-cresol) and para-cresol (p-cresol), and a weight average molecular weight of about 10,000. A polyhydroxystyrene resin was prepared as a base resin by substituting 30% (by mole) of a hydroxyl group of a polyhydroxystyrene resin (having a weight average molecular weight of about 14,000) with 1-ethoxyethoxy groups.

Solid components (including any solutes except for solvent), i.e., 66.9 wt % of the novolac resin having the acid decomposable (also photo-decomposable) protecting group (1-ethoxy-ethoxy group) as a base resin, 30 wt % of the polyhydroxystyrene resin having an acid decomposable protecting group as another base resin, 3 wt % of 2-styryl-4,6-bis(trichloromethyl)-1,3,5-triazine as a photoacid generator, and 0.1 wt % of a silicon-based surfactant were mixed with propylene glycol monoethyl acetate used as a solvent to prepare a photoresist composition. A weight ratio of the solute to the solvent in the photoresist composition was about 25:75.

### Example 3

A photoresist composition was prepared in the same manner as in Example 2, except that 46.9 wt %, instead of 66.9 wt %, of the novolac resin having the acid decomposable (also photo-decomposable) protecting group (1-ethoxy-ethoxy group) as a base resin, and 50 wt %, instead of 30 wt %, of the polyhydroxystyrene resin having an acid decomposable protecting group were used.

### Example 4

A photoresist composition was prepared in the same manner as in Example 2, except that 26.9 wt %, instead of 66.9 wt %, of the novolac resin having the acid decomposable (also photo-decomposable) protecting group (1-ethoxy-ethoxy group) as a base resin, and 70 wt %, instead of 30 wt %, of the polyhydroxystyrene resin having an acid decomposable protecting group were used.

### Example 5

A photoresist composition was prepared in the same manner as in Example 3, except that 1-phenoxyethoxy group, instead of 1-ethoxyethoxy group, was used to prepare the polyhydroxystyrene resin with acid decomposable protecting groups.

### Example 6

A photoresist composition was prepared in the same manner as in Example 4, except that 1-phenoxyethoxy group, instead of 1-ethoxyethoxy group, was used to prepare the polyhydroxystyrene resin with acid decomposable protecting groups.

### Example 7

A photoresist composition was prepared in the same manner as in Example 5, except that Compound 2 (oxime sulfonate), instead of Compound 1 (2-phenylstyryl-4,6-bis(trichloromethyl)-1,3,5-triazine), was used as the photoacid generator.

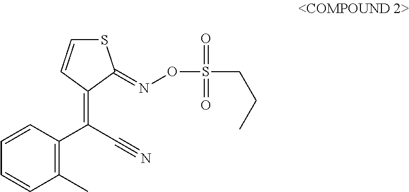 [SMILES: CCCS(=O)(=O)O/N=C1\SC=C\C1=C(\C#N)c1ccccc1C]

### Example 8

A photoresist composition was prepared in the same manner as in Example 5, except that a novolac resin having a weight ratio of 80:20, instead of 60:40, between meta-cresol (m-cresol) and para-cresol (p-cresol) was used.

### Example 9

A photoresist composition was prepared in the same manner as in Example 5, except that a novolac resin having a weight average molecular weight of about 20,000, instead of about 10,000, was used.

Each of the photoresist compositions of Examples 1 to 9 was coated on a glass substrate with an indium tin oxide (ITO) layer thereon to a thickness of about 2.0 μm and then exposed to light of composite wavelengths including g-line (435 nm), h-line (405 nm), and i-line (365 nm). Each of the exposed substrates was developed using a 2.38 wt % of aqueous tetramethylammonium hydroxide (TMAH) solution, and the ITO layer on the substrate was etched using an ITO etch solution (MA-SZ02, available from DONGWOO FINE-CHEM CO., LTD, Korea). The resulting etched substrate was observed by scanning electron microscopy (SEM). The results of etching the substrates coated with the photoresist compositions of Examples 1 to 9 are shown in Table 1. In Table 1, the amount (%) of each component is in % by weight (wt %) based on a total weight of the photoresist composition on solid basis (excluding the solvent), the molecular weight indicates a weight average molecular weight, and mole % of the protecting group indicates a percentage of the number of substituted protecting groups to the number of hydroxyl groups before substitution. All of the photoresist compositions of Examples 1 to 9 included 0.1 wt % of the silicon-based surfactant.

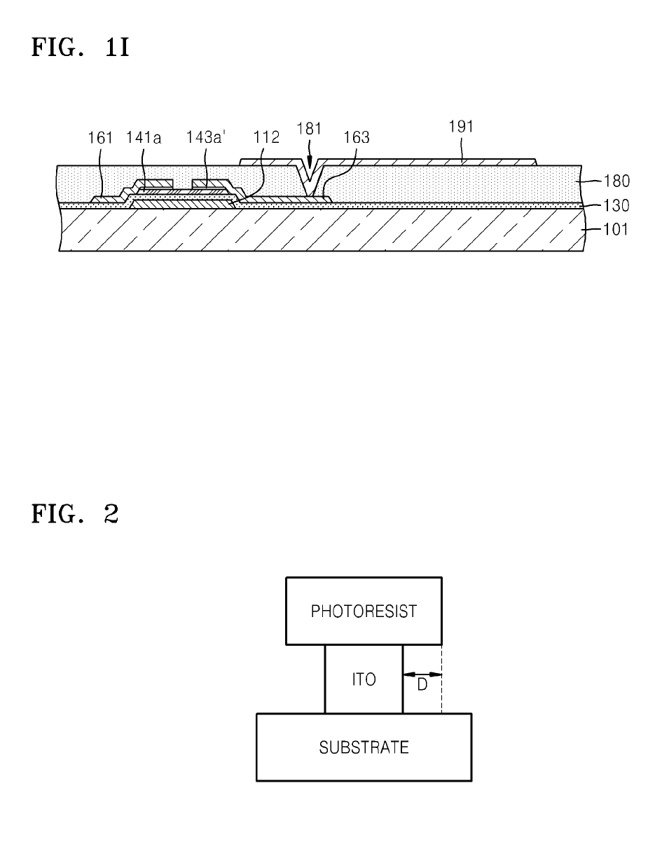

In Table 1, “undercut” refers to a region of an ITO pattern underlying a photoresist pattern recessed from a sidewall of the photoresist pattern as a result of wet etching, which is denoted by “D” in FIG. 2. The adhesion state in Table 2 indicates adhesion state between the photoresist layer and the ITO layer underlying the photoresist layer, wherein “good” means that the photoresist layer remained untaken away from the ITO layer, and “poor” means that the photoresist layer on the ITO layer was partially or fully removed.

TABLE 1

| | Novolac resin | | | | Polyhydroxystyrene resin | | | | | |
|---|---|---|---|---|---|---|---|---|---|---|
| | | | | Protecting | | | Protecting | | | |
| | Amount | Molecular | Meta/ | group | Amount | Molecular | group | PAG | Undercut | Adhesion |
| Ex. | (%) | Weight | Para | (20 mole %) | (%) | Weight | (30 mole %) | (3%) | (μm) | state |
| 1 | 96.9 | 10,000 | 60/40 | 1-ethoxy | — | — | — | triazine | 0.21 | Good |
| | | | | ethoxy | | | | | | |
| | | | | group | | | | | | |
| 2 | 66.9 | 10,000 | 60/40 | 1-ethoxy | 30 | 14,000 | 1-ethoxy | triazine | 0.22 | Good |
| | | | | ethoxy | | | ethoxy | | | |
| | | | | group | | | group | | | |
| 3 | 46.9 | 10,000 | 60/40 | 1-ethoxy | 50 | 14,000 | 1-ethoxy | triazine | 0.25 | Good |
| | | | | ethoxy | | | ethoxy | | | |
| | | | | group | | | group | | | |
| 4 | 26.9 | 10,000 | 60/40 | 1-ethoxy | 70 | 14,000 | 1-ethoxy | triazine | 0.77 | Poor |
| | | | | ethoxy | | | ethoxy | | | |
| | | | | group | | | group | | | |
| 5 | 46.9 | 10,000 | 60/40 | 1-ethoxy | 50 | 14,000 | 1-phenoxy | triazine | 0.24 | Good |
| | | | | ethoxy | | | ethoxy | | | |
| | | | | group | | | group | | | |
| 6 | 26.9 | 10,000 | 60/40 | 1-ethoxy | 70 | 14,000 | 1-phenoxy | triazine | 0.72 | Poor |
| | | | | ethoxy | | | ethoxy | | | |
| | | | | group | | | group | | | |
| 7 | 46.9 | 10,000 | 60/40 | 1-ethoxy | 50 | 14,000 | 1-phenoxy | oxime | 0.25 | Good |
| | | | | ethoxy | | | ethoxy | sulfonate | | |
| | | | | group | | | group | | | |
| 8 | 46.9 | 10,000 | 80/20 | 1-ethoxy | 50 | 14,000 | 1-ethoxy | triazine | 0.25 | Good |
| | | | | ethoxy | | | ethoxy | | | |
| | | | | group | | | group | | | |
| 9 | 46.9 | 20,000 | 60/40 | 1-ethoxy | 50 | 14,000 | 1-ethoxy | triazine | 0.25 | Good |
| | | | | ethoxy | | | ethoxy | | | |
| | | | | group | | | group | | | |

Referring to Table 1, in the photoresist compositions of Examples 4 and 6 in which the amount of the novolac resin is less than 30 wt %, the undercuts of the ITO patterns were wider, and the adhesion state of the photoresist was poor, compared to the other photoresist compositions. In the photoresist compositions of Examples 1 to 3, 5, and 7 to 9 in which the amount of the novolac resin is 40 wt % or greater, the undercut sizes of the ITO patterns were surprisingly appropriate, and the adhesion state of the photoresist was good, irrespective of the ratio of m-cresol to p-cresol and the molecular weight of the novolac resin, the amount of the polyhydroxystyrene resin, or the type of the protecting group.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the present disclosure have been described with reference to the figures, it will be understood by those of ordinary skill in the art that various changes in form and details may be made therein without departing from the spirit and scope of the present embodiments as defined by the following claims.

1. A photoresist composition comprising:
a solute comprising a novolac resin with an acid decomposable protecting group, and the solute further comprising a polyhydroxystyrene resin with an acid decomposable protecting group or an acrylic resin acid with an acid decomposable protecting group, and an amount of the novolac resin in the solute is in a range of about 40 wt % or greater to less than 100 wt % based on the weight of the solute; and
a photoacid generator; and
an organic solvent.

2. The photoresist composition of claim 1, wherein the amount of the solute is in a range of about 10 wt % to about 40 wt % based on a total weight of the chemically amplified photoresist composition, and the amount of the organic solvent is the remaining weight of the chemically amplified photoresist composition.

3. (canceled)

4. The photoresist composition of claim 1, wherein the acid decomposable protecting group of the novolac resin substitutes for part of a hydroxyl group of the novolac resin, and the acid decomposable protecting group comprises a tert-butyl group, a tert-butoxycarbonyl group, a tert-butoxycarbonylmethyl group, a tetrahydro-2-pyranyl group, a tetrahydro-2-furyl group, a 1-ethoxyethyl group, a 1-(2-methylpropoxyl)ethyl group, a 1-(2-methoxyethoxyl)ethyl group, a 1-(2-acetoxyethoxyl)ethyl group, a 1-[2-(1-adamantyloxy)ethoxy]ethyl group, a 1-[2-(1-adamantanecarbonyloxyl)ethoxy]ethyl group, a 3-oxocyclohexyl group, a 4-methyltetrahydro-2-pyrone-4-yl group, a 2-methyl-2-adamantyl group, or a 2-ethyl-2-adamantyl group.

5. The photoresist composition of claim 1, wherein the acid decomposable protecting group of the polyhydroxystyrene resin or the acrylic resin substitutes for part of a hydroxyl group of the polyhydroxystyrene resin or the acrylic resin, and the acid decomposable protecting group comprises a tert-butyl group, a tert-butoxycarbonyl group, a tert-butoxycarbonylmethyl group, a tetrahydro-2-pyranyl group, a tetrahydro-2-furyl group, a 1-ethoxyethyl group, a 1-(2-methylpropoxyl)ethyl group, a 1-(2-methoxyethoxyl)ethyl group, a 1-(2-acetoxyethoxyl)ethyl group, a 1-[2-(1-adamantyloxy)ethoxy]ethyl group, a 1-[2-(1-adamantanecarbonyloxyl)ethoxy]ethyl group, a 3-oxocyclohexyl group, a 4-methyltetrahydro-2-pyrone-4-yl group, a 2-methyl-2-adamantyl group, or a 2-ethyl-2-adamantyl group.

6. The photoresist composition of claim 1, wherein a weight ratio of meta-cresol to para-cresol used in polymerization of the novolac resin is in a range of about 40:60 to about 100:0.

7. The photoresist composition of claim 1, wherein the novolac resin has a weight average molecular weight of about 1,000 to about 30,000.

8. The photoresist composition of claim 1, wherein a mole ratio of the acid decomposable protecting group to a hydroxyl group in the novolac resin is in a range of about 10:90 to about 40:60.

9. The photoresist composition of claim 1, wherein a mole ratio of the acid decomposable protecting group in the polyhydroxystyrene resin or the acrylic resin to a hydroxyl group in the polyhydroxystyrene resin or the acrylic resin is in a range of about 20:80 to about 50:50.

10. The photoresist composition of claim 1, wherein the photoacid generator generates an acid in a wavelength range of light of about 365 nm to about 435 nm.

11. The photoresist composition of claim 1, wherein the organic solvent comprises propylene glycol monomethyl ether acetate, propyleneglycol monoethylether, ethyl lactate, benzyl alcohol, methyl acetate, ethyl acetate, n-butyl acetate, isobutyl acetate, propyl acetate, isobutyl acetate, or methyl-3-methoxypropionate.

12. The photoresist composition of claim 1, further comprising an additive or additives.

13. The photoresist composition of claim 1, wherein the additive comprises a surfactant, an adhesion enhancer, a neutralizing agent, or a UV light absorber.

14. The photoresist composition of claim 13, wherein the neutralizing agent comprises ethylamine, propylamine, butylamine, diisopropylaniline, diisopropylamine, or tris(2-(2-methoxyethoxyl)ethyl)amine.

15-20. (canceled)
